(19) United States
(12) Patent Application Publication
(10) Pub. No.: US 2026/0262251 A1
(43) Pub. Date: Sep. 3, 2026

(54) SEMICONDUCTOR DEVICE AND MANUFACTURING METHOD THEREOF

(71) Applicant: FUJI ELECTRIC CO., LTD., Kawasaki-shi (JP)

(72) Inventor: Syunki NARITA, Matsumoto-city (JP)

(73) Assignee: FUJI ELECTRIC CO., LTD., Kawasaki-shi (JP)

(21) Appl. No.: 19/439,107

(22) Filed: Jan. 2, 2026

(30) Foreign Application Priority Data
Feb. 28, 2025 (JP) 2025-032176

(51) Int. Cl. H10D 30/66; H10D 12/00; H10D 12/01; H10D 30/01; H10D 62/10

(52) U.S. Cl. CPC H10D 30/668; H10D 12/038; H10D 12/481; H10D 30/0297; H10D 62/107; H10D 62/126

(57) ABSTRACT

The semiconductor device includes: a drift layer of a first conductivity type; a base region of a second conductivity type, provided on a top surface side of the drift layer; a main region of the first conductivity type, provided on a top surface side of the base region; a first trench, and a second trench deeper than the first trench, the first trench and the second trench sandwiching the main region and the base region from lateral surface sides of the main region and the base region; insulated gate electrode structures buried in the first trench and the second trench; and a gate bottom protection region of the second conductivity type, provided at a bottom of the insulated gate electrode structure, the gate bottom protection region being provided for the second trench.

### CROSS-REFERENCE TO RELATED APPLICATION

This application claims benefit of priority under 35 USC 119 based on Japanese Patent Application No. 2025-032176 filed on Feb. 28, 2025, the entire contents of which are incorporated by reference herein.

### BACKGROUND OF THE INVENTION

### 1. Field of the Invention

This disclosure relates to a semiconductor device and manufacturing method thereof.

### 2. Description of the Related Art

JP 6631632 B2 (Patent Literature 1) and F. Udrea et al., “Experimental demonstration, challenges, and prospects of the vertical SiC FinFET”, 2022 IEEE 34th ISPSD, May 2022 (Non-Patent Literature 1) describe a vertical SiC-MOSFET having a trench gate structure incorporating unit cells (functional units of a device) configured with a FinFET structure (Metal Oxide Semiconductor Field Effect Transistor: a MOS field effect transistor including an insulated gate and having a three layer structure of Metal-Oxide Film-Semiconductor).

However, in Patent Literature 1 and Non-Patent Literature 1, the Fin width (the width between gate trenches adjacent to each other) is narrow. Because of this, carriers may be affected by JFET resistance.

### SUMMARY OF THE INVENTION

This disclosure is accomplished in view of the above problems, and an object of the present invention is to provide a semiconductor device in which JFET resistance is reduced and manufacturing method thereof.

In order to achieve the above object, a semiconductor device according to one aspect of this disclosure includes: a drift layer of a first conductivity type; a base region of a second conductivity type, provided on a top surface side of the drift layer; a main region of the first conductivity type, provided on a top surface side of the base region; a first trench, and a second trench deeper than the first trench, the first trench and the second trench sandwiching the main region and the base region from lateral surface sides of the main region and the base region; insulated gate electrode structures buried in the first trench and the second trench; and a gate bottom protection region of the second conductivity type, provided at a bottom of the insulated gate electrode structure, the gate bottom protection region being provided for the second trench.

The base region may have a width of 0.2 μm or less.

The gate bottom protection region may be provided only for the second trench. Respective gate bottom protection regions may be provided for the first trench and the second trench, and the gate bottom protection region provided for the first trench may have a width smaller than a width of the first trench.

The second trench may have a depth of 1.4 times or more and 5 times or less a depth of the first trench.

The first trench may include a plurality of first trenches, the second trench may include a plurality of second trenches, and the first trench and the second trench may be arranged alternately along an arrangement direction of the plurality of first trenches and the plurality of second trenches.

The first trench may include a plurality of first trenches, the second trench may include a plurality of second trenches, and a plurality of first trenches may be provided between an i-th second trench (i represents a positive integer) and an (i+1)th second trench as two second trenches among the plurality of second trenches along an arrangement direction of the plurality of first trenches and the plurality of second trenches.

The first trench may include a plurality of first trenches, the second trench may include a plurality of second trenches, and an i-th second trench (i represents a positive integer) and a (i+1)th second trench along an arrangement direction the plurality of first trenches and the plurality of second trenches may have different depths.

The semiconductor device may further include a first semiconductor region of the second conductivity type, configured to connect the gate bottom protection region provided for the second trench to the base region.

A semiconductor device manufacturing method includes: forming a drift layer of a first conductivity type; forming a base region of a second conductivity type, on a top surface side of the drift layer; forming a main region of the first conductivity type, on a top surface side of the base region; forming a first trench, and a second trench deeper than the first trench in such a manner that the first trench and the second trench sandwich the main region and the base region from lateral surface sides of the main region and the base region; burying insulated gate electrode structures in the first trench and the second trench; and forming a gate bottom protection region of the second conductivity type, at a bottom of the insulated gate electrode structure, the gate bottom protection region being formed for the second trench.

The base region sandwiched between the first trench and the second trench may be formed to have a width of 0.2 μm or less.

The second trench may be formed to have a depth of 1.4 times or more and 5 times or less a depth of the first trench.

A plurality of first trenches and a plurality of second trenches may be formed to be the first trench and the second trench are arranged alternately along an arrangement direction of the plurality of first trenches and the plurality of second trenches. The gate bottom protection region may be formed only for the second trench. Respective gate bottom protection regions may be formed for the first trench and the second trench. The gate bottom protection region formed for the first trench may have a width smaller than a width of the first trench.

Note that the summary of the disclosure does not describe all necessary features of this disclosure. Subcombinations of these features can also be included in the disclosure.

### BRIEF DESCRIPTION OF THE DRAWINGS

FIG. 1 is a sectional view illustrating a vertical section of a semiconductor device according to a first embodiment;

FIG. 2 is a sectional view illustrating a horizontal section viewed from the top surface side along a line A-A in FIG. 1;

FIG. 3 is a sectional view illustrating a vertical section viewed from bottom to top in FIG. 2 along a line B-B in FIG. 2.

FIG. 4 is a sectional view illustrating a vertical section of a semiconductor device according to a comparative example;

FIG. 5 is a process sectional view to describe an example of a semiconductor device manufacturing method according to the first embodiment;

FIG. 6 is a process sectional view subsequent to FIG. 5 to describe the example of the semiconductor device manufacturing method according to the first embodiment;

FIG. 7 is a process sectional view subsequent to FIG. 5 to describe the example of the semiconductor device manufacturing method according to the first embodiment;

FIG. 8 is a process sectional view subsequent to FIGS. 6 and 7 to describe an example of the semiconductor device manufacturing method according to the first embodiment;

FIG. 9 is a process sectional view subsequent to FIGS. 6 and 7 to describe an example of the semiconductor device manufacturing method according to the first embodiment;

FIG. 10 is a process sectional view subsequent to FIGS. 8 and 9 to describe the example of the semiconductor device manufacturing method according to the first embodiment;

FIG. 11 is a process sectional view subsequent to FIGS. 8 and 9 to describe the example of the semiconductor device manufacturing method according to the first embodiment;

FIG. 12 is a process sectional view subsequent to FIGS. 10 and 11 to describe the example of the semiconductor device manufacturing method according to the first embodiment;

FIG. 13 is a process sectional view subsequent to FIGS. 10 and 11 to describe the example of the semiconductor device manufacturing method according to the first embodiment;

FIG. 14 is a process sectional view subsequent to FIGS. 12 and 13 to describe the example of the semiconductor device manufacturing method according to the first embodiment;

FIG. 15 is a process sectional view subsequent to FIGS. 12 and 13 to describe the example of the semiconductor device manufacturing method according to the first embodiment;

FIG. 16 is a sectional view illustrating a vertical section of a semiconductor device according to a second embodiment;

FIG. 17 is a sectional view illustrating a vertical section of a semiconductor device according to a third embodiment; and

FIG. 18 is a sectional view illustrating a vertical section of a semiconductor device according to a fourth embodiment.

### DETAILED DESCRIPTION

With reference to the drawings, the following describes first to fourth embodiments of this disclosure. In the description for the drawings, identical or similar constituents have identical or similar reference signs, and redundant descriptions are omitted. Note that the drawings are schematic, and the relationship between thickness and flat dimension, the ratio between layer thicknesses, and the like may be different from actual ones. In addition, the drawings may include portions having different dimensional relationships or ratios. The first to fourth embodiments described below describe devices or methods to embody the technical idea of this disclosure, and the technical idea of this disclosure does not limit the materials, shapes, structures, arrangements, and the like of each constituent component to those described below.

In the present specification, the source region of a metal-oxide-semiconductor field-effect transistor (MOSFET) is “one main region (a first main region)” selectable as the emitter region of an insulated gate bipolar transistor (IGBT). In a thyristor such as an MOS-controlled static induction thyristor (SI thyristor), the “one main region” is selectable as a cathode region. The drain region of the MOSFET is “the other main region (a second main region)” of a semiconductor device that is selectable as a collector region in the IGBT or an anode region in the thyristor. When the “main region” is just referred to in the present specification, the “main region” indicates the appropriate one of the first main region and the second main region based on a common general technical knowledge of those skilled in the art.

Further, the definitions of directions such as “up” and “down” in the following description are merely definitions for convenience of the description and do not restrict the technical idea of this disclosure. For example, when a target is rotated by 90° and observed, the “up-down direction” is replaced with the “right-left direction,” and when the target is rotated by 180° and observed, the top and bottom are upside down. Also, “top surface” may be read as “front surface,” and “bottom surface” may be read as “back surface.”

The following description illustratively describes a case where a first conductivity type is n-type, and a second conductivity type is p-type. However, the conductivity types may be reversed such that the first conductivity type is p-type, and the second conductivity type is n-type. Sign “+” to be added to “n” or “p” indicates a semiconductor region having a relatively high impurity concentration in comparison with a semiconductor region without “+,” and sign “−” to be added to “n” or “p” indicates a semiconductor region having a relatively low impurity concentration in comparison with a semiconductor region without “−.” Note that separate semiconductor regions assigned with “n” may have different impurity concentrations.

In the following description, that impurity concentrations, widths, depths, thicknesses, and the like are “generally identical” to each other or “generally the same” includes a range of allowable errors due to process variation, in addition to the cases where they are strictly the same. The range of allowable errors is ±10%, for example.

### First Embodiment

### Configuration of Semiconductor Device

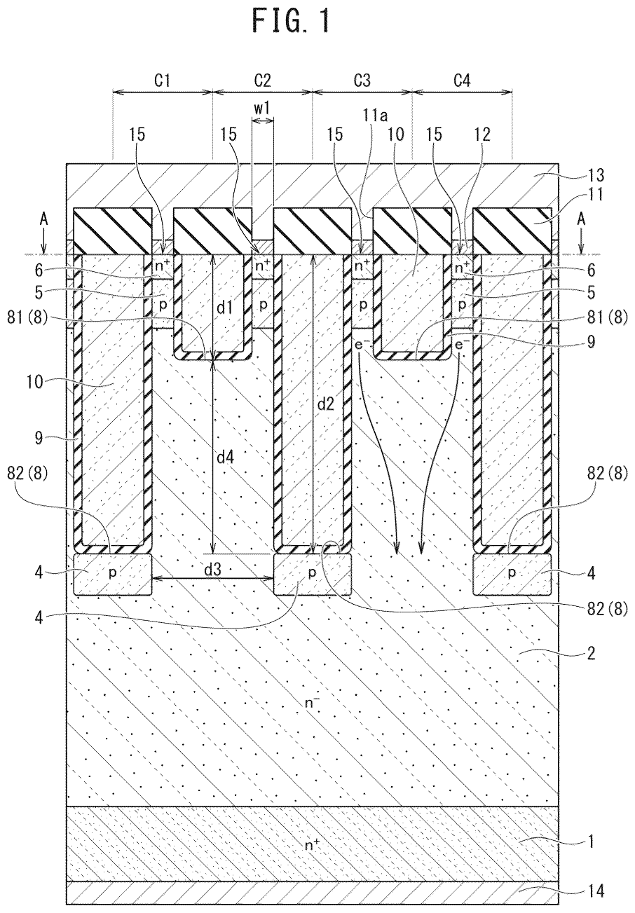

FIGS. 1 to 3 are views illustrating exemplary configurations of a semiconductor device according to a first embodiment of this disclosure. The semiconductor device according to the first embodiment is an insulated gate semiconductor device. As illustrated in FIG. 1, the semiconductor device according to the first embodiment illustrates an example in which an active element as a power switching element is a vertical MOSFET (SiC-MOSFET) having a trench-gate structure. The semiconductor device according to the first embodiment includes unit cells C1 to C4, which are functional units as the active element. The unit cells C1 to C4 are arranged in the right-left direction of FIG. 1. FIG. 1 illustrates four unit cells C1 to C4, but the semiconductor device according to the first embodiment may have a multichannel structure further including more cells arranged in a similar manner.

The semiconductor device according to the first embodiment includes a drift layer 2, which is a semiconductor region of a first conductivity type (n⁻-type). The drift layer 2 is constituted by an epitaxially-grown layer made of silicon carbide (SiC), for example. The impurity concentration and thickness of the drift layer 2 can be adjusted appropriately according to the breakdown voltage rating and other design specifications. The drift layer 2 has an impurity concentration of approximately about 1×10¹⁵ cm⁻³ or more and 5×10¹⁶ cm⁻³ or less, for example.

In each of the unit cells C1 to C4, a base region 5, which is a semiconductor region of a second conductivity type (p-type), is provided on the top surface side of the drift layer 2. The base region 5 is constituted by an epitaxially-grown layer made of SiC, for example. The base region 5 has an impurity concentration of approximately 1×10¹⁷ cm⁻³ or more and 1×10¹⁸ cm⁻³ or less, for example.

In each of the unit cells C1 to C4, a first main region (source region) 6, which is a semiconductor region of a first conductivity type (n⁺-type) with a higher impurity concentration than that of the drift layer 2, are provided on the top surface side of the base region 5. The source region 6 is constituted by an epitaxially-grown layer made of SiC, for example. The source region 6 has an impurity concentration of approximately 1×10¹⁷ cm⁻³ or more and 5×10¹⁸ cm⁻³ or less, for example.

In the normal direction (depth direction) of the top surface of the source region 6, the source region 6 is etched downward from the top surface, so that a trench 8 extending through the source region 6 and the base region 5 is provided. The trench 8 include two types of trenches having different depths, that is, a first trench 81, and a second trench 82 deeper than the first trench 81. When the first trench 81 and the second trench 82 are not distinguished from each other, they are just referred to as the trench 8. The bottom surface of the trench 8 reaches the drift layer 2. The lateral surface of the trench 8 is in contact with respective lateral surfaces of the source region 6, the base region 5, and the drift layer 2.

As illustrated in FIG. 1, each of the unit cells C1 to C4 includes a mesa section, which is a semiconductor region sandwiched between the trenches 8 adjacent to each other, as a Fin section 15. More specifically, each of the unit cells C1 to C4 includes a mesa section, which is a semiconductor region sandwiched between the first trench 81 and the second trench 82 adjacent to each other, as the Fin section 15. The Fin section 15 includes the source region 6, the base region 5, and a portion of the drift layer 2 which portion is sandwiched between the first trench 81 and the second trench 82 adjacent to each other.

The Fin section 15 has a width w1 corresponding to the width of the source region 6, the width of the base region 5, and the width of the portion of the drift layer 2 which portion is sandwiched between the trenches 8 adjacent to each other. The width w1 of the Fin section 15 is smaller than a width w2 of the trench 8. The width w1 of the Fin section 15 is approximately 0.2 μm or less, for example. The width w1 of the Fin section 15 is approximately 0.05μm or more and 0.2μm or less, for example. The width w1 of the Fin section 15 may be approximately 0.1 μm or more and 0.2 μm or less, and may be approximately 0.05 μm or more but 0.1 μm or less. When the width w1 of the Fin section 15 is approximately 0.2 μm or less, a FinFET structure (described later) can be achieved.

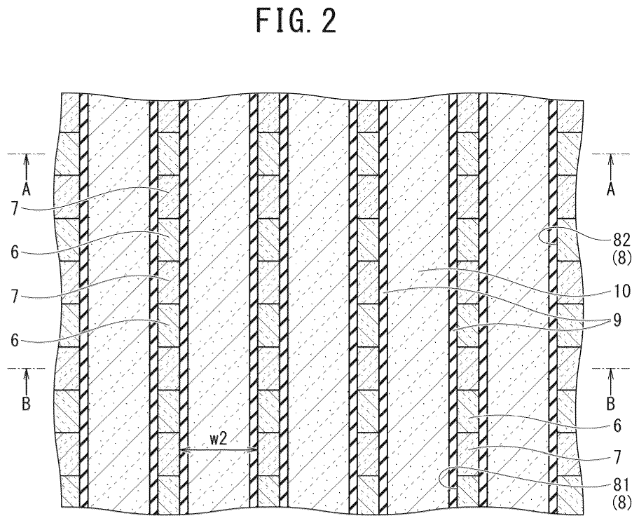

FIG. 2 is a sectional view illustrating a horizontal section viewed from the top surface side along a line A-A in FIG. 1. A vertical section viewed from bottom to top in FIG. 2, along a line A-A in FIG. 2, corresponds to FIG. 1. As illustrated in FIG. 2, the trenches 8, gate insulating films 9, and gate electrodes 10 form a plane pattern in which they extend linearly (in a stripe shape) in one direction (the up-down direction in FIG. 2), in parallel to each other. The trenches 8 are arranged in parallel to each other at an interval (a first interval) along a direction (the right-left direction, the arrangement direction in FIG. 2) perpendicular to the one direction. The source region 6 and a base contact region 7 as a semiconductor region of a second conductivity type (p⁺-type) are provided alternately and periodically in the one direction (the up-down direction in FIG. 2) between the trenches 8. The source region 6 and the base contact region 7 may be in contact with each other.

As illustrated in FIG. 1, the semiconductor device according to the present embodiment includes a plurality of first trenches 81 and a plurality of second trenches 82, and the first trench 81 and the second trench 82 are provided alternately and periodically at the interval (the first interval) along the right-left direction (the arrangement direction) on the surface of paper of FIG. 1.

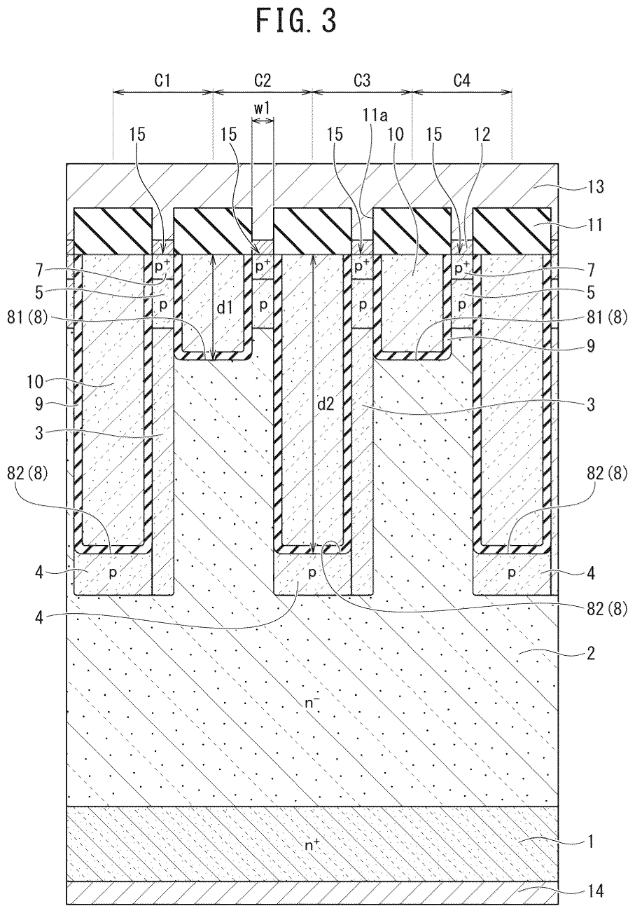

FIG. 3 illustrates a vertical section viewed from bottom to top in FIG. 2, along a line B-B in FIG. 2. As illustrated in FIG. 3, in each of the unit cells C1 to C4, the base contact region 7 is provided on the top surface side of the base region 5. The depth of the base contact region 7 may be the same as the depth of the source region 6 illustrated in FIG. 1, may be deeper than the depth of the source region 6, or may be shallower than the depth of the source region 6. The bottom surface of the base contact region 7 is in contact with the top surface of the base region 5. The lateral surface of the base contact region 7 is in contact with the lateral surface of the trench 8. The base contact region 7 is constituted by an epitaxially-grown layer made of SiC, for example. The base contact region 7 has a higher impurity concentration than the impurity concentration of the base region 5. The base contact region 7 has an impurity concentration of approximately 5×10¹⁹ cm⁻³ or more and 5×10²⁰ cm⁻³ or less, for example. On the section illustrated in FIG. 3, the Fin section 15 includes the base contact region 7, the base region 5, and a portion of the drift layer 2 which portion is sandwiched between the trenches 8 adjacent to each other.

A gate insulating film 9 is provided along the bottom surface and the lateral surfaces of the trench 8. A gate electrode 10 is buried in the trench 8 via the gate insulating film 9. A trench-gate insulated gate electrode structure (9, 10) is constituted by the gate insulating film 9 and the gate electrode 10. The insulated gate electrode structure (9, 10) is buried in each of the first trench 81 and the second trench 82. In the present example, the first trench 81 and the second trench 82 are not dummy trenches. The second trench 82 may be a dummy trench.

The gate insulating film 9 has a thickness of approximately 30 nm or more and 100 nm or less, for example. The gate insulating film 9 may be a single layer film composed of any one of a silicon oxide film (SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film, or a composite film formed by stacking some of these films. The material usable for the gate electrode 10 may be, for example, a polysilicon layer (a doped polysilicon layer) doped with p-type impurities or n-type impurities at a high impurity concentration, or high melting point metals such as titanium (Ti), tungsten (W), or nickel (Ni).

An insulating film 11, which is an interlayer insulating film, is provided on the top surface side of the gate electrode 10. The insulating film 11 may be, for example, a single layer film composed of a silicon oxide film (SiO₂ film) called a “NSG film,” which does not contain impurities, a silicon oxide film (PSG film) to which phosphorus is added, a silicon oxide film (BSG film) to which boron is added, a silicon oxide film (BPSG film) to which phosphorus and boron are added, or a silicon nitride film (Si₃N₄ film), or a composite film formed by stacking some of these films.

As illustrated in FIGS. 1, 3, the insulating film 11 has an opening (contact hole) 11a that exposes at least part of the top surfaces of the source region 6 and the base contact region 7. A silicide layer 12 in direct contact with the top surfaces of the source region 6 and the base contact region 7 is provided in the opening 11a. The silicide layer 12 is made of nickel silicide (NiSix) or the like and is provided to establish ohmic contact. Note that 3C-SiC may be formed instead of the silicide layer 12.

A first main electrode (source electrode) 13 is provided to cover the top surfaces of the insulating film 11 and the silicide layer 12. The source electrode 13 is provided to be separated from a gate wiring layer (not illustrated) electrically connected to the gate electrode 10. The source electrode 13 is made of a metal such as aluminum (Al) or copper (Cu), or an alloy such as aluminum-silicon (Al—Si) or aluminum-copper (Al—Cu), for example. Note that a contact plug to bury the opening 11a may be provided in the opening 11a and on the top surface of the silicide layer 12. The contact plug is made of a metal material such as tungsten (W), for example, and has a top surface in contact with the bottom surface of the source electrode 13. Although not illustrated herein, a barrier metal layer may be provided on the bottom surface side of the source electrode 13. The barrier metal layer is made of a metal such as titanium nitride (TiN), titanium (Ti), or a metal having a stacking structure of TiN/Ti with Ti provided as a lower layer, for example. The barrier metal layer may cover the insulating film 11.

As illustrated in FIG. 1, a gate bottom protection region 4, which is a semiconductor region of the second conductivity type (p⁺-type), is provided within the drift layer 2. The gate bottom protection region 4 is provided for the second trench 82. That “the gate bottom protection region 4 is provided for the second trench 82” means that “the gate bottom protection region 4 is provided at the bottom of the insulated gate electrode structure (9, 10) buried in the second trench 82.” The gate bottom protection region 4 is provided only for the second trench 82, out of the first trench 81 and the second trench 82. The gate bottom protection region 4 has a function to relieve the electric field applied to the gate insulating film 9 on the bottom surface of the second trench 82. The gate bottom protection region 4 has an impurity concentration of approximately 1×10¹⁷ cm⁻³ or more and 1×10¹⁹ cm⁻³ or less, for example. On the forward side or the rearward side of FIG. 1, the gate bottom protection region 4 may be electrically connected to the base region 5. For example, as illustrated in FIG. 3, the gate bottom protection region 4 may be electrically connected to the base region 5 via a first semiconductor region 3 of a second conductivity type (p-type), below the base contact region 7. The first semiconductor region 3 is elongated in the up-down direction on the surface of paper of FIG. 3, and its lower end is connected to the gate bottom protection region 4 while its upper end is connected to the base region 5. The first semiconductor region 3 has an impurity concentration of approximately 1×10¹⁷ cm⁻³ or more and 1×10¹⁹ cm⁻³ or less, for example. Note that the first semiconductor region 3 needs to be provided below at least some of the base contact regions 7.

FIG. 1 illustrates an example in which the gate bottom protection region 4 is in contact with the bottom surface of the trench 8, but the gate bottom protection region 4 may be separated from the bottom surface of the trench 8. FIG. 1 illustrates an example in which the width of the gate bottom protection region 4 provided for the second trench 82 is generally the same as the width w2 of the second trench 82. However, the width of the gate bottom protection region 4 may be narrower than the width w2 of the second trench 82 or may be wider than the width w2 of the second trench 82, provided that electric field concentration can be suppressed.

A second main region (drain region) 1, which is a semiconductor region of the first conductivity type (n⁺-type) with a higher impurity concentration than that of the drift layer 2, is provided on the bottom surface side of the drift layer 2. The drain region 1 is constituted by a semiconductor substrate (SiC substrate) made of SiC, for example. The drain region 1 has an impurity concentration of approximately 1×10¹⁹ cm⁻³ or more and 3×10²⁰ cm⁻³ or less, for example. Note that a buffer layer, a dislocation conversion layer, a recombination promotion layer, or the like, which is an n-type semiconductor region layer with an impurity concentration higher than that of the drift layer 2 and lower than that of the drain region 1, may be provided between the drift layer 2 and the drain region 1.

A second main electrode (drain electrode) 14 is provided on the bottom surface side of the drain region 1. The drain electrode 14 may be a single layer film made of gold (Au), for example, or a metal film formed by stacking titanium (Ti), nickel (Ni), and Au in this order from the drain region 1 side, and a metal film made of molybdenum (Mo), tungsten (W), or the like may be further stacked as the lowest layer of the drain electrode 14. A silicide layer made of nickel silicide (NiSiₓ) or the like to establish ohmic contact may be provided between the drain region 1 and the drain electrode 14.

At the time of switching the semiconductor device according to the first embodiment, a positive voltage is applied to the drain electrode 14 with the source electrode 13 at ground potential. When a positive voltage equal to or more than a threshold is applied to the gate electrode 10 in that state, an inversion layer (channel) is formed in the base region 5 in each of the unit cells C1 to C4, and the vertical MOSFET is brought into an ON state. In the ON state, current flows from the drain electrode 14 to the source electrode 13 via the drain region 1, the drift layer 2, the inversion layer of the base region 5, and the source region 6. In the meantime, in the case where the voltage applied to the gate electrodes 10 is less than the threshold, no inversion layer is formed in the base region 5, so that the vertical MOSFET is turned off, and no current flows from the drain electrode 14 to the source electrode 13.

In the semiconductor device according to the first embodiment, the vertical MOSFET has a FinFET structure. The FinFET structure is a so-called double-gate structure, in which the width w1 of the Fin section 15 sandwiched between adjacent trenches 8 is narrowed by a predetermined width, and an inversion layer (channel) is formed in the base region 5 sandwiched between the adjacent trenches 8. In the FinFET, when a gate voltage equal to or more than a threshold is applied to the gate electrodes 10, voltages from a pair of (two) gate electrodes 10 sandwiching the base region 5 are applied to the whole base region 5. Here, the width w1 of the Fin section 15 has the above value, and therefore, in each of the unit cells C1 to C4, one inversion layer is formed not in the vicinity of the interface between the base region 5 and each of right and left gate insulating films 9, but in a region (a bulk region) of the base region 5 which region is separated from the interface between the base region 5 and each of the right and left gate insulating films 9. The inversion layer is formed in a region of the base region 5 which region is separated from the interface between the base region 5 and each of the right and left gate insulating films 9 by approximately 0.05 μm or more and 0.1 μm or less, for example. The inversion layer is formed in a middle portion of the base region 5 in the horizontal direction.

Thus, in the semiconductor device according to the first embodiment, electrons moving in the inversion layer are less susceptible to the interface state density of the interface between the gate insulating film 9 and the base region 5, in comparison with the case where an inversion layer is formed in the vicinity of the interface between the base region 5 and the gate insulating film 9. As a result, electronic mobility can be raised, and on-resistance can be reduced.

Particularly, SiC is a compound, and the interface state density of SiC is approximately one order of magnitude higher than that of Si. Accordingly, the electron mobility of the semiconductor device formed with SiC is more susceptible to interface state density than a semiconductor device formed with Si. Because of this, the FinFET structure is particularly effective for the semiconductor device formed with SiC.

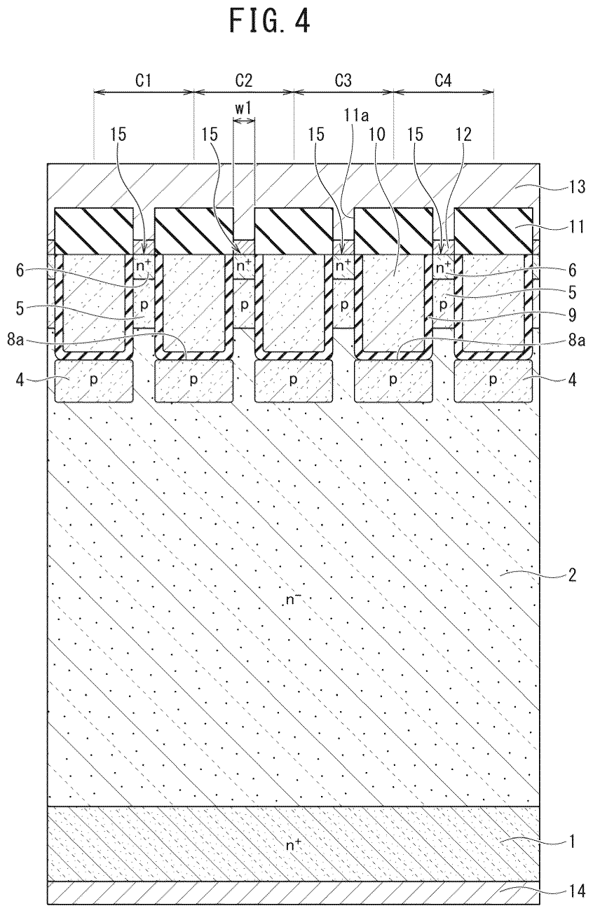

The following describes an overview of this disclosure, and the first trench 81 and the second trench 82 more in detail. Note that, in the following description, that “the first trench 81 is provided” means that the insulated gate electrode structure (9, 10) buried in the first trench 81 is provided, as well as the first trench 81 is provided. Similarly, that “the second trench 82 is provided” means that the insulated gate electrode structure (9, 10) buried in the second trench 82 is provided, as well as the second trench 82 is provided. First described is the overview of this disclosure. FIG. 4 is a view illustrating a longitudinal sectional structure of a semiconductor device according to a comparative example. As illustrated in FIG. 4, in the unit cells C1 to C4 of the semiconductor device according to the comparative example, trenches 8a have generally the same depth. Respective gate bottom protection regions 4 are provided at the bottoms of all the trenches 8a in the unit cells C1 to C4. As a result, in the right-left direction on the surface of paper of FIG. 4, the interval between the gate bottom protection regions 4 adjacent to each other is generally the same as the width w1 of the Fin section 15, thereby consequently increasing JFET resistance and on-resistance. However, if the gate bottom protection regions 4 are not provided, the electric field concentrates at the bottoms of the trenches 8a. Since the band gap of SiC is wide, the electric field applied to the gate insulating film tends to be strong, and it is important to protect a gate bottom portion.

In the semiconductor device according to the present embodiment, the second trench 82 has a depth d2 larger than a depth d1 of the first trench 81, as illustrated in FIG. 1. By providing the trenches 8 having different depths, the electric field tends to concentrate at the bottom of the trench (the second trench 82) with a deeper depth, and the electric field tends not to concentrate at the bottom of the trench (the first trench 81) with a shallower depth. Accordingly, in the present embodiment, the gate bottom protection region 4 is provided at the bottom of the second trench 82 at which the electric field tends to concentrate, and no gate bottom protection region 4 is provided at the bottom of the first trench 81 at which the electric field tends not to concentrate. The gate bottom protection region 4 is provided for every other trench 8 among the trenches 8 thus arranged. This makes it possible to increase an interval d3 (JFET width) between the gate bottom protection regions 4 adjacent to each other and to reduce JFET resistance.

The depth d2 of the second trench 82 is approximately 1.4 times or more and 5 times or less the depth d1 of the first trench 81, for example. Since the depth d2 of the second trench 82 is 1.4 times or more the depth d1 of the first trench 81, it is possible to suppress the electric field concentration at the bottom of the first trench 81 and to secure a current path through which current flows. In other words, when a distance d4 from the bottom surface of the first trench 81 to the top surface of the gate bottom protection region 4 is set to 0.4 times or more the depth d1 of the first trench 81, it is possible to suppress the electric field concentration at the bottom of the first trench 81 and to secure a given area for the drift layer 2 as a current path below the first trench 81. FIG. 1 illustrates the flow of current (electrons). Note that the distance d4 corresponds to the difference between the depth d2 of the second trench 82 and the depth d1 of the first trench 81, for example. When the depth d2 of the second trench 82 is five times or less the depth d1 of the first trench 81, it is possible to suppress excessive complexity in forming the second trench 82. The height (the dimension in the up-down direction) of the Fin section 15 is determined by the depth d1 of the first trench 81. Accordingly, by designing the depth d1 of all the first trenches 81 to be as uniform as possible, the heights of the plurality of Fin sections 15 can be made as uniform as possible, although manufacturing errors occur.

The width w2 of the trench 8 (FIG. 2) is approximately 0.3 μm or more and 1.0 μm or less, for example. Note that the width of the first trench 81 and the width of the second trench 82 may be the same or may be different from each other. As illustrated in FIG. 1, the depth d1 of the first trench 81 is approximately 0.7 μm or more and 1.3 μm or less, for example. The interval d3 between the gate bottom protection regions 4 adjacent to each other is approximately 0.8 μm or more and 2.0 μm or less, for example. The distance d4 from the bottom surface of the first trench 81 to the top surface of the gate bottom protection region 4 is approximately 0.4 μm or more and 4.0 μm or less, for example. The aspect ratio of the interval d3 between the gate bottom protection regions 4 adjacent to each other to the difference (the distance d4) between the depth d2 of the second trench 82 and the depth d1 of the first trench 81 may be approximately 2:1 or more and 1:2 or less.

Since the semiconductor device according to the first embodiment includes the first trench 81, and the second trench 82 deeper than the first trench 81, the first trench 81 and the second trench 82 sandwiching the source region 6 and the base region 5 from their lateral surface sides, it is possible to suppress electric field concentration at the first trench 81. Accordingly, it is possible to relieve electric field concentration at the first trench 81 without providing the gate bottom protection region 4 for the first trench 81. The gate bottom protection region 4 is provided only for the second trench 82 at which the electric field tends to concentrate, out of the first trench 81 and the second trench 82. Since the gate bottom protection region 4 is selectively provided only for a portion at which electric field tends to concentrate, it is possible to increase the interval d3 between the gate bottom protection regions 4 and to reduce JFET resistance. This makes it possible to reduce on-resistance.

In the semiconductor device according to the first embodiment, the width w1 of the base region 5 is 0.2 μm or less. In the FinFET structure in which the width w1 is narrow, no gate bottom protection region 4 is provided for the bottom of the first trench 81, and the gate bottom protection region 4 provided for the bottom of the second trench 82 is located at a position separated downward from the lower side base of the Fin section 15. Accordingly, even in a case where the width of the Fin section 15 is narrow, it is possible to reduce the influence of JFET resistance.

In the semiconductor device according to the first embodiment, the depth of the second trench 82 is 1.4 times or more and 5 times or less the depth of the first trench 81. This makes it possible to secure a given area for the drift layer 2 as a current path below the first trench 81 and to reduce on-resistance. Besides, it is possible to suppress excessive complexity in forming the second trench 82.

In the semiconductor device according to the first embodiment, the first trench 81 and the second trench 82 are arranged alternately along the arrangement direction. Since the gate bottom protection region 4 is provided for every other trench 8 among the trenches 8 thus arranged, it is possible to increase the interval d3 (JFET width) between the gate bottom protection regions 4 adjacent to each other and to reduce JFET resistance.

The semiconductor device according to the first embodiment includes the first semiconductor region 3 of the second conductivity type, configured to connect the gate bottom protection region 4 provided for the second trench 82 to the base region 5. This makes it possible to fix the potential of the gate bottom protection region 4.

### Semiconductor Device Manufacturing Method

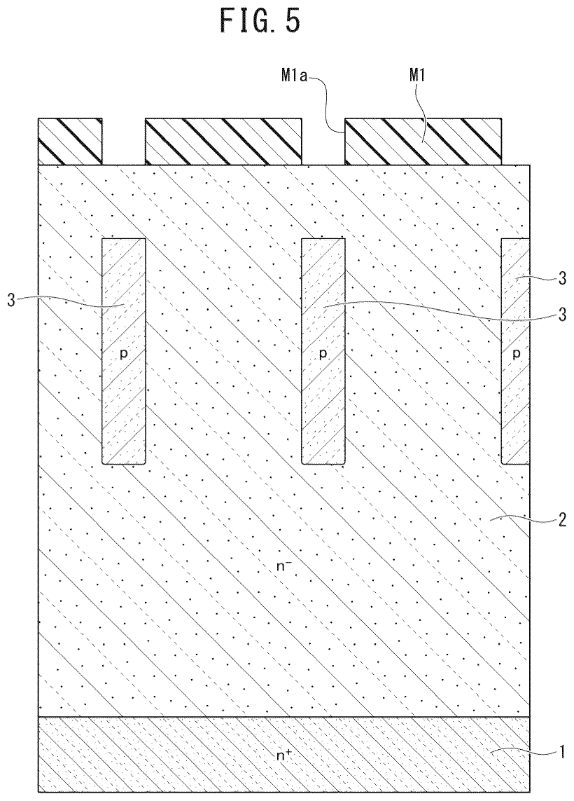

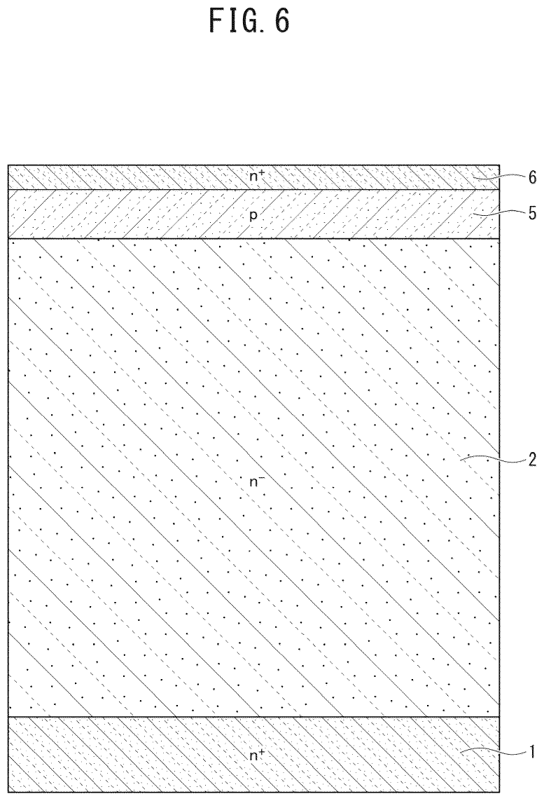

Referring now to FIG. 1 and FIGS. 5 to 15, an example of a method for manufacturing the semiconductor device according to the first embodiment illustrated in FIG. 1 will be described. Note that FIGS. 6, 8, 10, 12, 14 each illustrate a vertical section viewed from bottom to top in FIG. 2, along the line A-A in FIG. 2. FIGS. 5, 7, 9, 11, 13, 15 each illustrate a vertical section viewed from bottom to top in FIG. 2, along the line B-B in FIG. 2.

As illustrated in FIG. 5, first, the n⁺-type SiC semiconductor substrate (SiC substrate) 1 to which n-type impurities such as nitrogen (N) are added is prepared. The top surface of the SiC substrate 1 has an off angle of approximately 3 degrees or more and 8 degrees or less from a {0001} plane, for example. Subsequently, the drift layer 2 is epitaxially grown on the top surface side of the SiC substrate 1. After that, a mask pattern M1 for ion implantation, made of a photoresist film or the like, is formed on the top surface side of the drift layer 2 by use of a photolithography technique. Note that the mask pattern M1 may be a hard mask made of an insulating film or the like. Openings M1a are formed on portions of the mask pattern M1 in which portions the first semiconductor regions 3 are to be provided. Each opening M1a is provided at a position overlapping a region in which the base contact region 7 is to be formed and is arranged to minimize overlap with a region in which the source region 6 is to be formed. The ion implantation of p-type impurities such as aluminum (Al) is performed under a predetermined ion implantation condition with the use of the mask pattern M1 as a mask for ion implantation, so that the first semiconductor regions 3 are formed selectively. After that, the mask pattern M1 is removed. Note that the mask pattern M1 may be a hard mask made of an insulating film or the like.

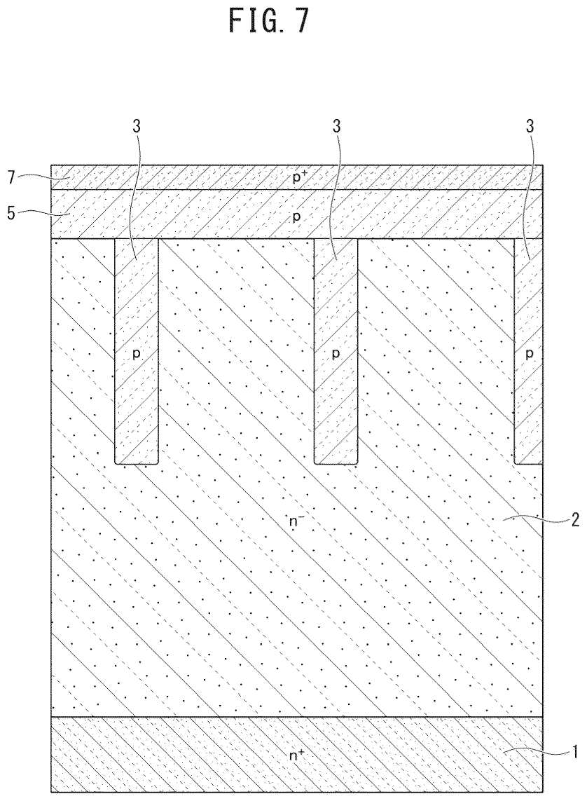

Subsequently, as illustrated in FIGS. 6, 7, the ion implantation of p-type impurities such as aluminum (Al) is performed on the top surface side of the drift layer 2 under a predetermined ion implantation condition, so that the base region 5 is formed selectively. The bottom surface of the base region 5 thus formed is in contact with the top surfaces of the first semiconductor regions 3. Then, the source region 6 illustrated in FIG. 6 and the base contact region 7 illustrated in FIG. 7 are formed selectively on the top surface side of the base region 5. The source region 6 is formed selectively by performing ion implantation of n-type impurities such as nitrogen (N) on the top surface side of the base region 5 under a predetermined ion implantation condition. The base contact region 7 is formed selectively by performing ion implantation of p-type impurities such as aluminum (Al) on the top surface side of the base region 5 under a predetermined ion implantation condition.

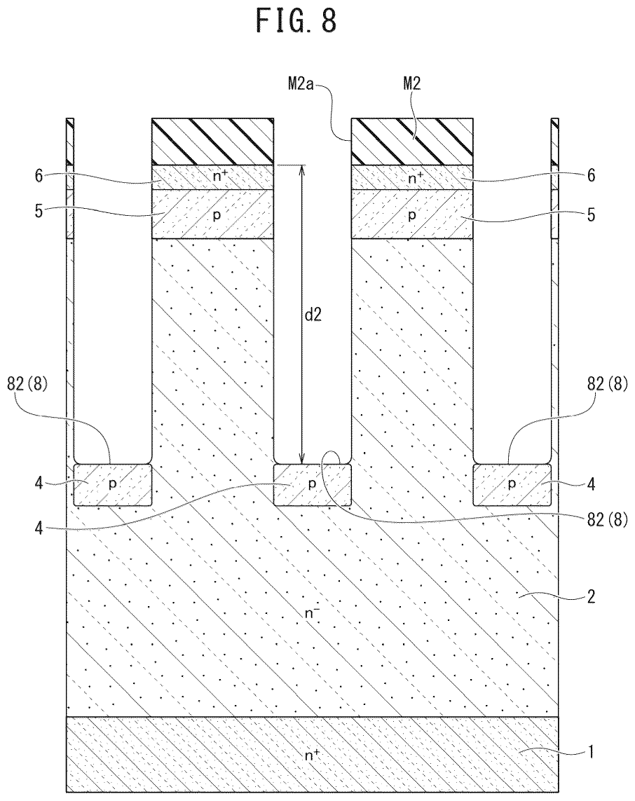

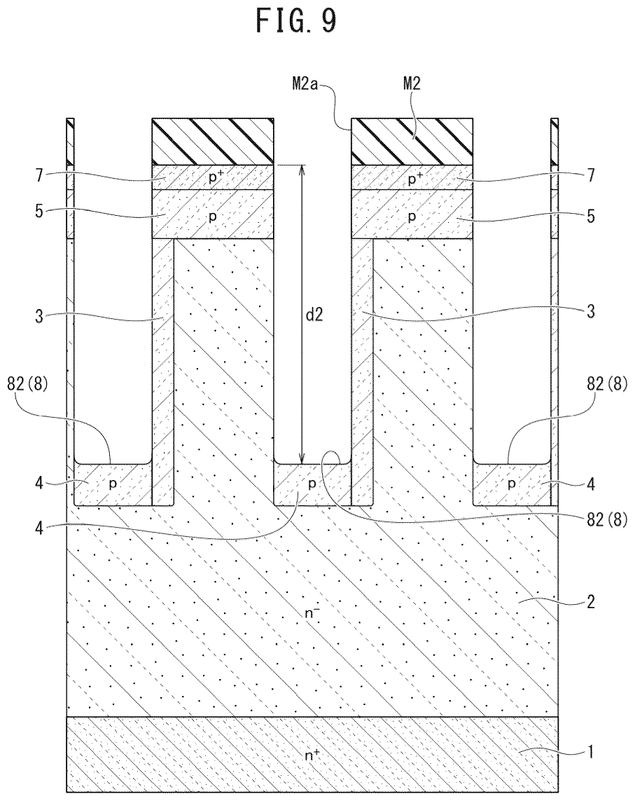

As illustrated in FIGS. 8, 9, a mask pattern M2 for etching, made of a photoresist film or the like, is formed on the top surface sides of the source region 6 and the base contact region 7 by use of the photolithography technique. Note that the mask pattern M2 may be a hard mask made of an insulating film or the like. The mask pattern M2 has a plurality of openings M2a arranged periodically at an interval in the right-left direction on the surface of paper of FIGS. 8, 9. With the use of the mask pattern M2 as a mask for etching, the second trenches 82 with the depth d2 are selectively formed in the depth direction from the top surfaces of the source region 6 and the base contact region 7 by a dry etching technique such as reactive ion etching (RIE). A plurality of second trenches 82 is arranged periodically at an interval in the right-left direction on the surface of paper of FIGS. 8, 9. Note that, as illustrated in FIG. 9, each of the openings M2a of the mask pattern M2 is located at a position offset from its corresponding first semiconductor region 3 in the right-left direction on the surface of paper of FIG. 9. Accordingly, a right portion of the first semiconductor region 3 on the surface of paper remains without being etched, and the remaining portion of the first semiconductor region 3 is in contact with the right side wall of its corresponding second trench 82.

After that, as illustrated in FIGS. 8, 9, the gate bottom protection regions 4 are selectively formed by performing ion implantation of p-type impurities such as aluminum (Al) into the drift layer 2 from the bottom surfaces of the second trenches 82 under a predetermined ion implantation condition. As illustrated in FIG. 9, the lateral surface of each of the gate bottom protection regions 4 thus formed is in contact with the lateral surface of its corresponding first semiconductor region 3.

Subsequently, by performing heat treatment (activation annealing), the p-type impurities or the n-type impurities thus ion-implanted into each of the first semiconductor region 3, the gate bottom protection region 4, the base region 5, the source region 6, the base contact region 7, and so on are activated all at once. The present embodiment deals with an example in which one activation annealing is performed after all ion implantation steps are finished, but activation annealing may be performed multiple times each after each of the ion implantation steps is performed.

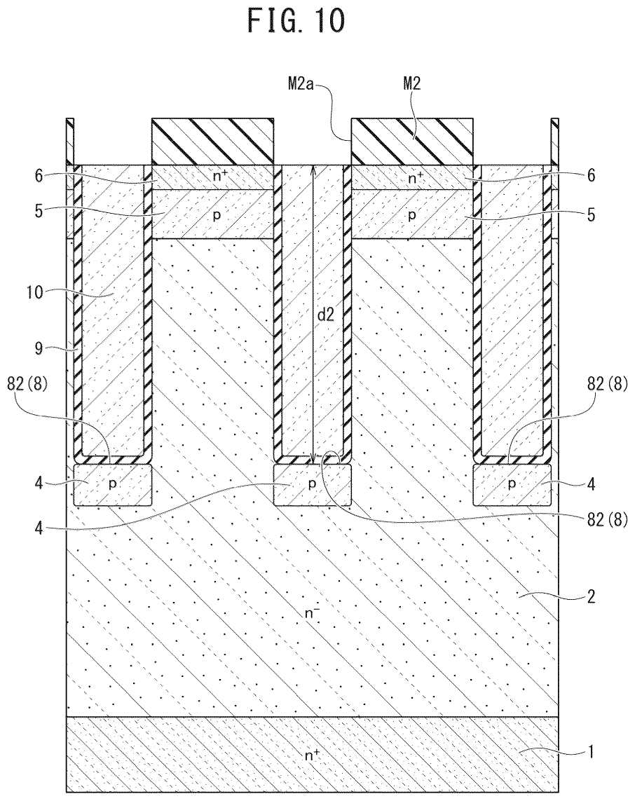

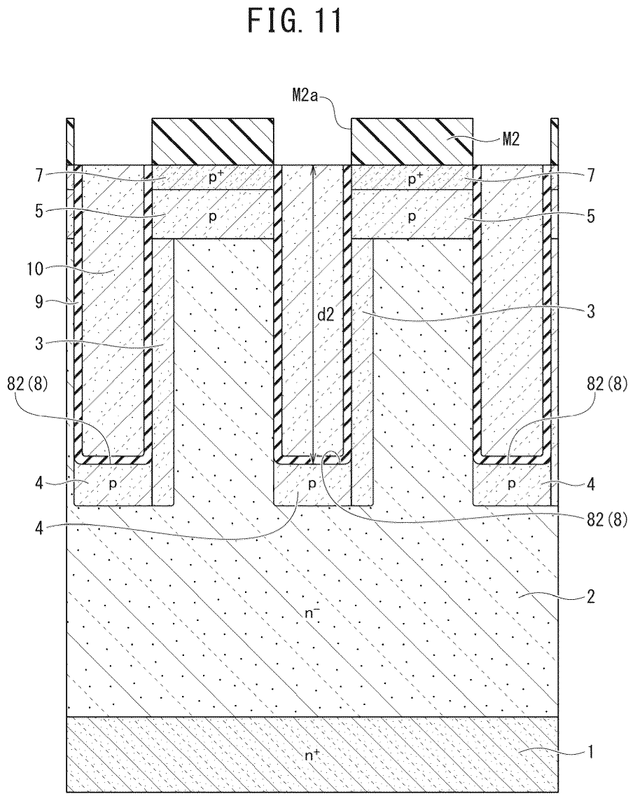

Subsequently, as illustrated in FIGS. 10, 11, the gate insulating film 9 is formed on the bottom surface and the lateral surface of each of the second trenches 82 by a thermal oxidation method, a CVD method, or the like. Subsequently, a polysilicon layer (a doped polysilicon layer) doped with impurities such as phosphorus (P) or boron (B) at a high impurity concentration is deposited into each of the second trenches 82 by the CVD technique or the like. Then, part of the polysilicon layer is selectively removed by dry etching or the like. As a result, as illustrated in FIGS. 10, 11, the insulated gate electrode structure (9, 10) constituted by the gate insulating film 9 and the gate electrode 10 is formed inside each of the second trenches 82. After that, the mask pattern M2 is removed.

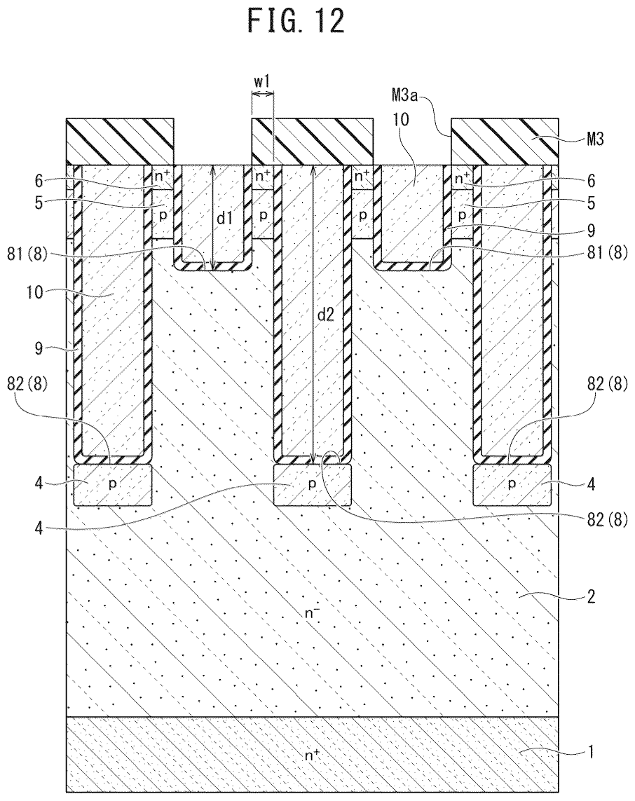

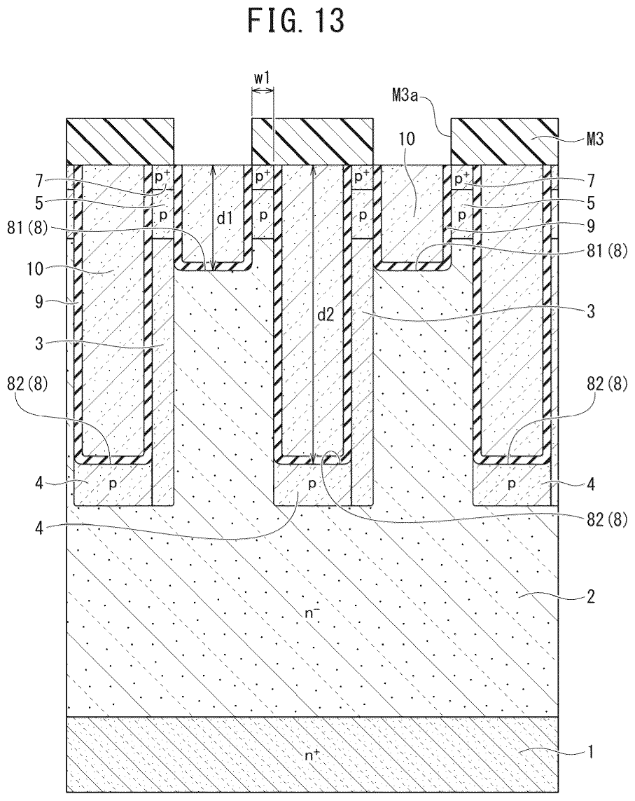

As illustrated in FIGS. 12, 13, a mask pattern M3 for etching, made of a photoresist film or the like, is formed on the top surface sides of the source region 6 and the base contact region 7 by use of the photolithography technique. Note that the mask pattern M3 may be a hard mask made of an insulating film or the like. The mask pattern M3 has a plurality of openings M3a arranged periodically at an interval in the right-left direction on the surface of paper of FIGS. 12, 13. Each of the openings M3a is located between the second trenches 82 adjacent to each other in the right-left direction on the surface of paper of FIGS. 12, 13. With the use of the mask pattern M3 as a mask for etching, the first trenches 81 with the depth d1 are selectively formed in the depth direction from the top surfaces of the source region 6 and the base contact region 7 by the dry etching technique such as reactive ion etching (RIE). Hereby, the first trench 81 having the depth d1 and the second trench 82 having the depth d2 are formed to be arranged alternately in the right-left direction on the surface of paper of FIGS. 12, 13. Note that the depth d2 is deeper than the depth d1. More specifically, the depth d2 of the second trench 82 is formed to be approximately 1.4 times or more and 5 times or less the depth d1 of the first trench 81. Since the first trenches 81 and the second trenches 82 are formed separately, the second trenches 82 can be formed to be deeper than the first trenches 81. The width w2 of the first trench 81 and the second trench 82 and the arrangement pitch of the first trench 81 and the second trench 82 are adjusted so that the width of the base region 5 sandwiched between the first trench 81 and the second trench 82 is approximately 0.2 μm or less. No gate bottom protection region 4 is not formed at the bottom of the first trench 81.

Then, the gate insulating film 9 is formed on the bottom surface and the lateral surface of each of the first trenches 81 by the thermal oxidation method, the CVD method, or the like. Subsequently, a polysilicon layer (a doped polysilicon layer) doped with impurities such as phosphorus (P) or boron (B) at a high impurity concentration is deposited into each of the first trenches 81 by the CVD technique or the like. After that, part of the polysilicon layer is selectively removed by dry etching or the like. As a result, as illustrated in FIGS. 12, 13, the insulated gate electrode structure (9, 10) constituted by the gate insulating film 9 and the gate electrode 10 is formed inside each of the first trenches 81. A semiconductor region remaining between the first trench 81 and the second trench 82 forms the Fin section 15. After that, the mask pattern M3 is removed. The gate insulating films 9 and the gate electrodes 10 for the first trench 81 and the second trench 82 may be formed at the same time.

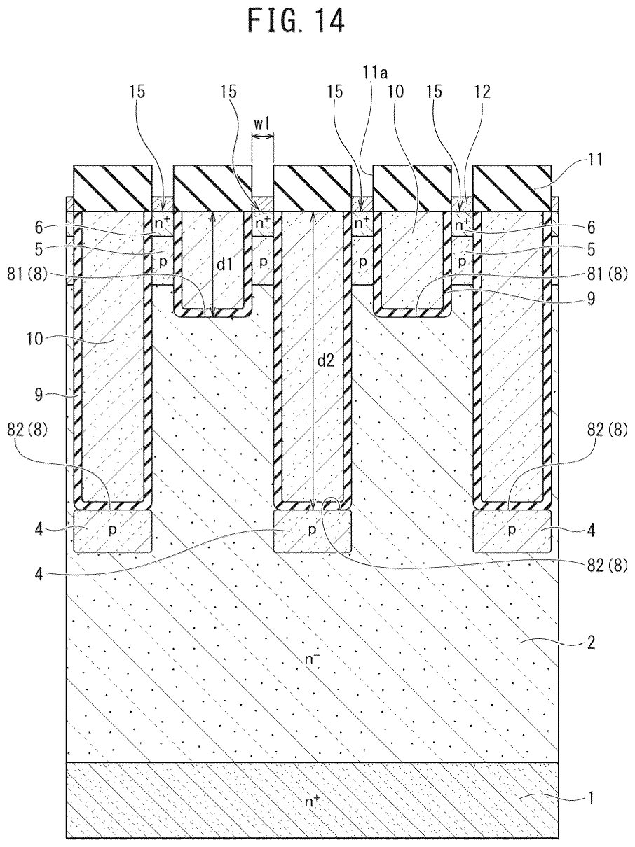

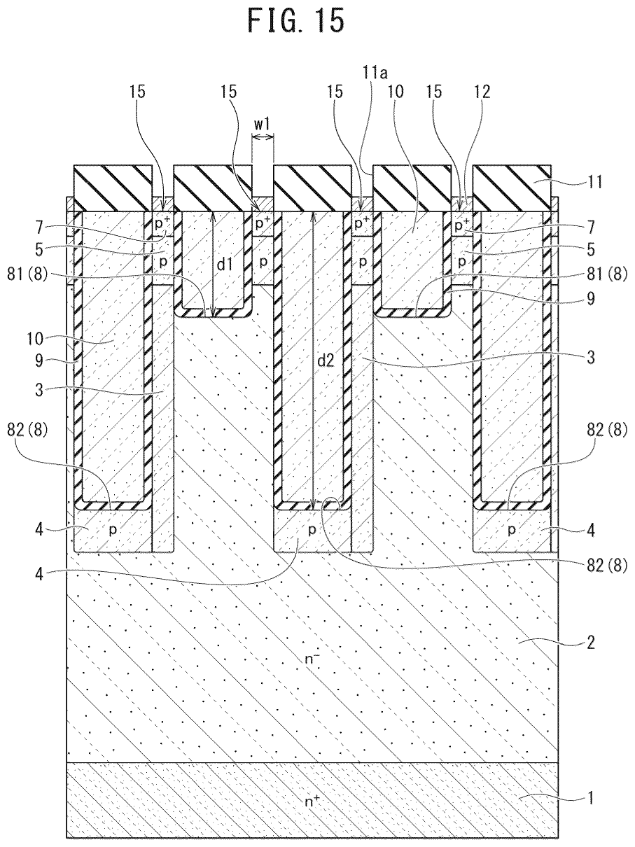

Subsequently, as illustrated in FIGS. 14, 15, the insulating film 11, which is an interlayer insulating film, is deposited on the top surface of the insulated gate electrode structure (9, 10) by the CVD technique or the like. Subsequently, part of the insulating film 11 is selectively removed by the photolithography technique, the dry etching technique, and the like to form, in the insulating film 11, the openings (contact holes) 11a that expose the top surfaces of the source region 6 and the base contact region 7. After that, heat treatment (reflow) to flatten the insulating film 11 may be performed.

Subsequently, the silicide layer 12 and the source electrode 13 (see FIG. 1), the silicide layer 12 being in contact with the top surfaces of the source region 6 and the base contact region 7, are sequentially formed by a sputtering technique, an evaporation method, or the like. A barrier metal layer may be formed on the bottom surface side of the source electrode 13.

Subsequently, the SiC substrate 1 is reduced in thickness from the bottom surface side by grinding, chemical mechanical polishing (CMP), or the like so as to adjust its thickness, and hereby, the drain region 1 is formed. Subsequently, the drain electrode 14 (see FIG. 1) made of titanium (Ti), nickel (Ni), gold (Au), or the like is formed on the entire bottom surface of the drain region 1 by the sputtering method, the evaporation method, or the like. Thus, the silicon carbide semiconductor device illustrated in FIG. 1 is completed.

Note that, in the formation method of the first semiconductor region 3, the second trenches 82 are formed as illustrated in FIG. 9 after ion implantation of p-type impurities is performed as illustrated in FIG. 5. However, the present disclosure is not limited to this. The second trenches 82 may be formed first, and after that, ion implantation of p-type impurities may be performed to form the first semiconductor region 3. At this time, ion implantation of p-type impurities is performed diagonally toward one side wall of each of the second trenches 82.

In the semiconductor device manufacturing method described above, the first trenches 81 are formed after the second trenches 82 are formed. However, the second trenches 82 may be formed after the first trenches 81 are formed.

In the semiconductor device manufacturing method according to the first embodiment, the first trench 81, and the second trench 82 deeper than the first trench 81 are formed to sandwich the source region 6 and the base region 5 from their lateral surface sides, thereby making it is possible to suppress electric field concentration at the bottom of the first trench 81, which is shallower. Hereby, it is possible to relieve electric field concentration at the first trench 81 without forming the gate bottom protection region 4 for the first trench 81. The gate bottom protection region 4 is formed only for the second trench 82 at which the electric field tends to concentrate, out of the first trench 81 and the second trench 82. Since the gate bottom protection region 4 is selectively formed only for a portion at which the electric field tends to concentrate, it is possible to increase the interval d3 between the gate bottom protection regions 4 and to reduce JFET resistance. This makes it possible to reduce on-resistance.

In the semiconductor device manufacturing method according to the first embodiment, the width w1 of the base region 5 is set to 0.2 μm or less by adjusting the interval between the first trench 81 and the second trench 82. In the FinFET structure in which the width w1 is small, no gate bottom protection region 4 is formed for the bottom of the first trench 81, and the gate bottom protection region 4 formed at the bottom of the second trench 82 is located at a position separated downward from the lower side base of the Fin section 15. Accordingly, even if the width of the Fin section 15 is narrow, it is possible to reduce the influence of JFET resistance.

In the semiconductor device manufacturing method according to the first embodiment, the depth of the second trench 82 is 1.4 times or more and 5 times or less the depth of the first trench 81. This makes it possible to secure a given area for the drift layer 2 as a current path below the first trench 81 and to reduce on-resistance. Besides, it is possible to suppress excessive complexity in forming the second trench 82.

In the semiconductor device manufacturing method according to the first embodiment, the first trench 81 and the second trench 82 are formed alternately along the arrangement direction. Accordingly, the gate bottom protection region 4 is formed for every other trench 8 among the trenches 8 thus arranged. This makes it possible to increase the interval d3 (JFET width) between the gate bottom protection regions 4 adjacent to each other and to reduce JFET resistance.

### Second Embodiment

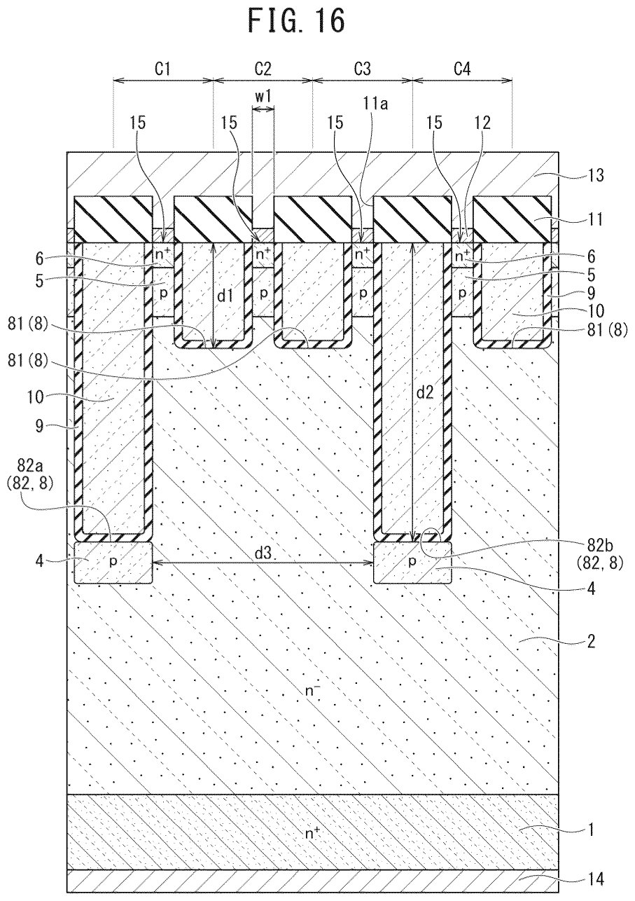

A semiconductor device according to a second embodiment is different from the semiconductor device according to the first embodiment illustrated in FIG. 1, in that a plurality of first trenches 81 is provided between two second trenches 82, i.e., an i-th second trench 82 (i represents a positive integer) and an (i+1)th second trench 82 along the arrangement direction, as illustrated in FIG. 16.

In order to distinguish the two second trenches 82 illustrated in FIG. 16 from each other, the second trench 82 on the left side in the right-left direction on the surface of paper is referred to as a second trench 82a, and the second trench 82 on the right side in the right-left direction on the surface of paper is referred to as a second trench 82b. When the second trench 82a and the second trench 82b are not distinguished from each other, they are just referred to as the second trench 82. For example, the second trench 82a corresponds to the i-th second trench 82 along the arrangement direction, and the second trench 82b corresponds to the (i+1)th second trench 82 along the arrangement direction. Two first trenches 81 are provided between the second trench 82a and the second trench 82b. The number of first trenches 81 provided between the second trench 82a and the second trench 82b is not limited to two. The number (a positive integer) of first trenches 81 provided between the second trench 82a and the second trench 82b may be two or more and five or less, for example, or may be two or three, for example. As the interval between the second trench 82a and the second trench 82b becomes larger, the electric field tends to concentrate at the bottom of the first trench 81. Accordingly, the number of first trenches 81 provided between the second trench 82a and the second trench 82b may be determined based on the interval between the second trench 82a and the second trench 82b or the difference in trench depth. Note that the arrangement of the first trenches 81 and the second trenches 82, such as one second trench 82, two first trenches 81, one second trench 82, and two first trenches 81, is repeated along the arrangement direction.

With the semiconductor device according to the second embodiment, since the number of second trenches 82 is reduced, it is possible to further increase the interval d3 between the gate bottom protection regions 4 adjacent to each other and to further reduce JFET resistance.

### Third Embodiment

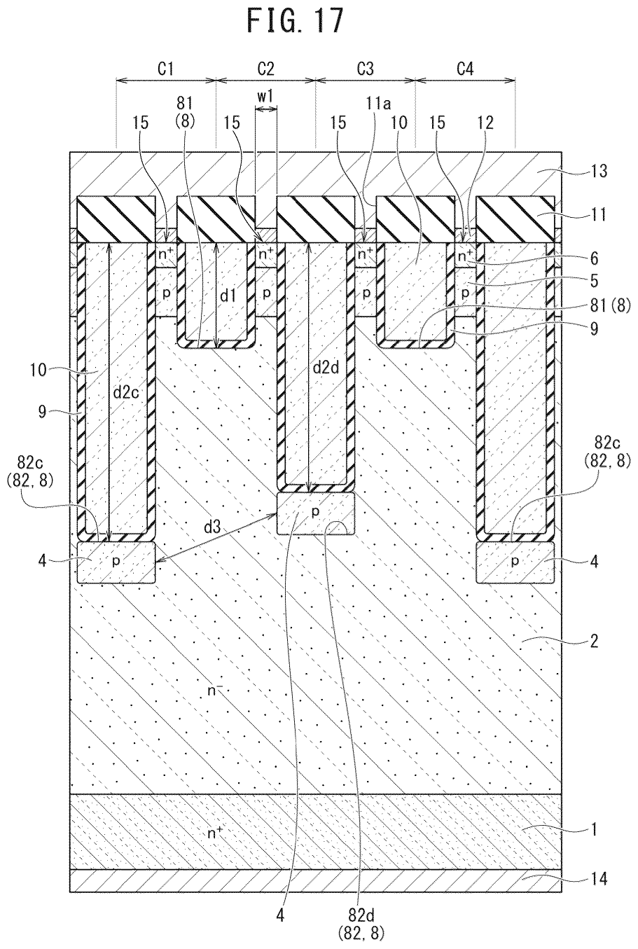

A semiconductor device according to a third embodiment is different from the semiconductor device according to the first embodiment illustrated in FIG. 1 in that the i-th second trench 82 (i represents a positive integer) and the (i+1)th second trench 82 along the arrangement direction have different depths, as illustrated in FIG. 17.

As illustrated in FIG. 17, the second trench 82 includes a second trench 82 having a depth d2c, and a second trench 82 having a depth d2d different from the depth d2c. The second trench 82 having the depth d2c is referred to as a second trench 82c, and the second trench 82 having the depth d2d is referred to as a second trench 82d, so that they are distinguished from each other. When the second trench 82c and the second trench 82d are not distinguished from each other, they are just referred to as the second trench 82. For example, the second trench 82c corresponds to the i-th second trench 82 along the arrangement direction, and the second trench 82d corresponds to the (i+1)th second trench 82 along the arrangement direction. The depth d2c of the second trench 82c and the depth d2d of the second trench 82d are approximately 1.4 times or more and 5 times or less the depth d1 of the first trench 81. In such a range, the depth d2c of the second trench 82c is larger than the depth d2d of the second trench 82d. Accordingly, the gate bottom protection region 4 provided at the bottom of the second trench 82c is located at a position deeper than the gate bottom protection region 4 provided at the bottom of the second trench 82d. In other words, the gate bottom protection regions 4 adjacent to each other are provided along a diagonal direction on the surface of paper of FIG. 17.

In the semiconductor device according to the third embodiment, since the second trench 82c and the second trench 82d have different depths, the interval d3 between the gate bottom protection regions 4 adjacent to each other is an interval along the diagonal direction on the surface of paper of FIG. 17. This makes it possible to increase the interval d3 as compared to the first embodiment illustrated in FIG. 1 and to further reduce JFET resistance.

### Fourth Embodiment

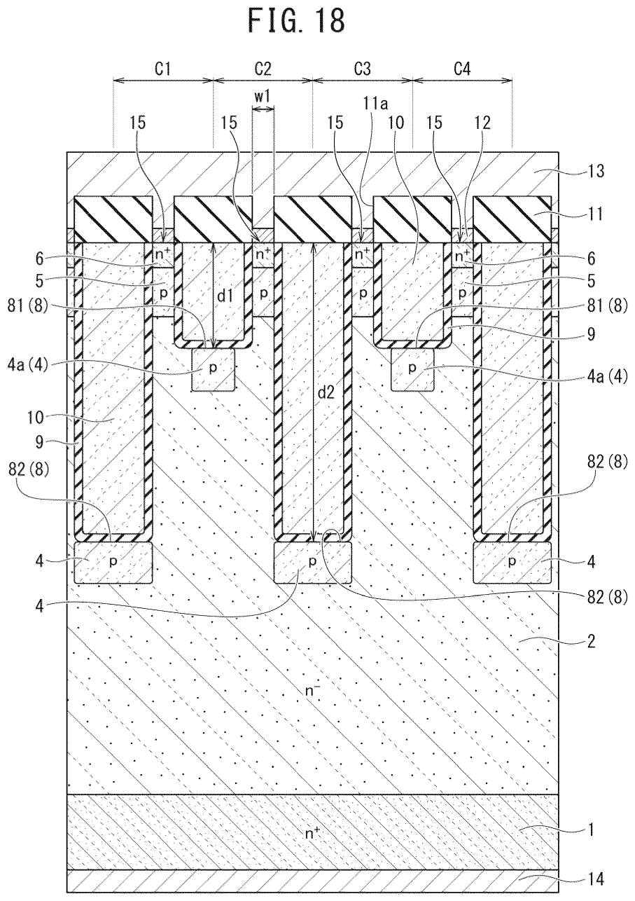

A semiconductor device according to a fourth embodiment is different from the semiconductor device according to the first embodiment illustrated in FIG. 1 in that respective gate bottom protection regions 4 are provided for the first trench 81 and the second trench 82, as illustrated in FIG. 18.

The gate bottom protection region 4 provided at the bottom of the first trench 81 is referred to as a gate bottom protection region 4a and is distinguished from the gate bottom protection region 4 provided at the bottom of the second trench 82. When the gate bottom protection region 4a is not distinguished from the gate bottom protection region 4, they are just referred to as the gate bottom protection region 4. In the right-left direction on the surface of paper of FIG. 18, the width of the gate bottom protection region 4a is smaller than the width of the first trench 81. That “the gate bottom protection region 4a is provided for the first trench 81” means that “the gate bottom protection region 4a is provided at the bottom of the insulated gate electrode structure (9, 10) buried in the first trench 81.” The gate bottom protection region 4a may be electrically connected to the base region 5 or may be set to a floating potential. The gate bottom protection region 4a can be formed by implanting p-type impurities at the same timing as the first semiconductor region 3, for example.

In the semiconductor device according to the fourth embodiment, since the gate bottom protection region 4a is provided at the bottom of the first trench 81, the electric field becomes less likely to concentrate at the bottom of the first trench 81. Since the width of the gate bottom protection region 4a is smaller than the width of the first trench 81, it is possible to prevent the p-type gate bottom protection region 4a from entering between a p-type region of the lower side base of the Fin section 15 and the drift layer 2 below the p-type region, thereby making it possible to suppress an increase in on-resistance.

### Other Embodiments

The first to fourth embodiments of this disclosure have been described above, but it should not be understood that the description and the drawings as part of this disclosure restrict this disclosure. Various alternative embodiments, examples, and operational technologies will become clear to a person skilled in the art from this disclosure.

For example, the MOSFET is described as an example of the semiconductor devices according to the first to fourth embodiments. However, the present invention is also applicable to an insulated gate bipolar transistor (IGBT) configured such that a p⁺-type collector region is provided instead of the n⁺-type drain region 1. Other than a single IGBT, the present invention is also applicable to a reverse conductive IGBT (RC-IGBT) or a reverse blocking insulated gate bipolar transistor (RB-IGBT).

A current spreading layer (CSL) of the first conductivity type (n-type) with a higher impurity concentration than that of the drift layer 2 may be selectively provided on the top surface side of the drift layer 2. The following describes a configuration in which the current spreading layer is provided. The bottom surface of the current spreading layer is in contact with the top surface of the drift layer 2. The current spreading layer is constituted by an epitaxially-grown layer made of SiC, for example. The current spreading layer has an impurity concentration of approximately 5×10¹⁶ cm⁻³ or more and 5×10¹⁷ cm⁻³ or less, for example. The bottom surface of the base region 5 is in contact with the top surface of the current spreading layer. The right and left lateral surfaces of the trench 8 are in contact with the current spreading layer instead of the drift layer 2, and the bottom surface of the trench 8 reaches the current spreading layer. The current spreading layer is located between the trenches 8 adjacent to each other. The gate bottom protection region 4 is provided in the current spreading layer.

The semiconductor layer of each of the semiconductor devices according to the first to fourth embodiments is made of silicon carbide (SiC) but may be made of silicon (Si), for example. That the semiconductor layer of the semiconductor device is made of SiC or Si may include a case where the semiconductor layer mainly contains SiC or Si.

The configurations disclosed in the first to fourth embodiments can be combined appropriately as far as no consistency occurs. It is needless to say that this disclosure includes various embodiments and so on that are not described herein. Accordingly, the technical scope of this disclosure is determined only by the invention specification matter according to appropriate claims from the above description.

1. A semiconductor device comprising:
a drift layer of a first conductivity type;
a base region of a second conductivity type, provided on a top surface side of the drift layer;
a main region of the first conductivity type, provided on a top surface side of the base region;
a first trench, and a second trench deeper than the first trench, the first trench and the second trench sandwiching the main region and the base region from lateral surface sides of the main region and the base region;
insulated gate electrode structures buried in the first trench and the second trench; and
a gate bottom protection region of the second conductivity type, provided at a bottom of the insulated gate electrode structure, the gate bottom protection region being provided for the second trench.

2. The semiconductor device according to claim 1, wherein
the base region has a width of 0.2 μm or less.

3. The semiconductor device according to claim 1, wherein
the gate bottom protection region is provided only for the second trench.

4. The semiconductor device according to claim 1, wherein:
respective gate bottom protection regions are provided for the first trench and the second trench; and
the gate bottom protection region provided for the first trench has a width smaller than a width of the first trench.

5. The semiconductor device according to claim 1, wherein
the second trench has a depth of 1.4 times or more and 5 times or less a depth of the first trench.

6. The semiconductor device according to claim 1, wherein:
the first trench includes a plurality of first trenches;
the second trench includes a plurality of second trenches; and
the first trench and the second trench are arranged alternately along an arrangement direction of the plurality of first trenches and the plurality of second trenches.

7. The semiconductor device according to claim 1, wherein:
the first trench includes a plurality of first trenches;
the second trench includes a plurality of second trenches; and
a plurality of first trenches is provided between an i-th second trench (i represents a positive integer) and an (i+1)th second trench as two second trenches among the plurality of second trenches along an arrangement direction of the plurality of first trenches and the plurality of second trenches.

8. The semiconductor device according to claim 1, wherein:
the first trench includes a plurality of first trenches;
the second trench includes a plurality of second trenches; and
an i-th second trench (i represents a positive integer) and a (i+1)th second trench along an arrangement direction the plurality of first trenches and the plurality of second trenches have different depths.

9. The semiconductor device according to claim 1, further comprising:
a first semiconductor region of the second conductivity type, configured to connect the gate bottom protection region provided for the second trench to the base region.

10. A semiconductor device manufacturing method comprising:
forming a drift layer of a first conductivity type;
forming a base region of a second conductivity type, on a top surface side of the drift layer;
forming a main region of the first conductivity type, on a top surface side of the base region;
forming a first trench, and a second trench deeper than the first trench in such a manner that the first trench and the second trench sandwich the main region and the base region from lateral surface sides of the main region and the base region;
burying insulated gate electrode structures in the first trench and the second trench; and
forming a gate bottom protection region of the second conductivity type, at a bottom the insulated gate electrode structure, the gate bottom protection region being formed for the second trench.

11. The semiconductor device manufacturing method according to claim 10, wherein
the base region sandwiched between the first trench and the second trench is formed to have a width of 0.2 μm or less.

12. The semiconductor device manufacturing method according to claim 10, wherein
the second trench is formed to have a depth of 1.4 times or more and 5 times or less a depth of the first trench.

13. The semiconductor device manufacturing method according to claim 10, wherein
a plurality of first trenches and a plurality of second trenches are formed to be the first trench and the second trench are arranged alternately along an arrangement direction of the plurality of first trenches and the plurality of second trenches.

14. The semiconductor device manufacturing method according to claim 10, wherein
the gate bottom protection region is formed only for the second trench.

15. The semiconductor device manufacturing method according to claim 10, wherein:
respective gate bottom protection regions are formed for the first trench and the second trench; and
the gate bottom protection region formed for the first trench has a width smaller than a width of the first trench.
